(19) United States
(12) Patent Application Publication
(10) Pub. No.: US 2015/0237741 A1
(43) Pub. Date: Aug. 20, 2015

(54) PRINTED CIRCUIT BOARD AND MANUFACTURING METHOD THEREOF

(71) Applicants: Samsung Electro-Mechanics Co., Ltd., Suwon (KR); Korea Advanced Institute of Science and Technology, Daejeon (KR)

(72) Inventors: Yong Jin PARK, Suwon (KR); Sung Gap Im, Daejeon (KR); Young Gwan Ko, Suwon (KR); Jae Bum You, Namyangju (KR); Shin Young Kim, Daejeon (KR)

(73) Assignees: SAMSUNG ELECTRO-MECHANICS CO., LTD., Suwon (KR); KOREA ADVANCED INSTITUTE OF SCIENCE AND TECHNOLOGY, Daejeon (KR)

(21) Appl. No.: 14/333,734

(22) Filed: Jul. 17, 2014

(30) Foreign Application Priority Data
Feb. 17, 2014 (KR) 10-2014-0017989

(51) Int. Cl. H05K 3/38; H05K 3/10; H05K 1/09

(52) U.S. Cl. CPC H05K 3/38; H05K 1/09; H05K 3/384; H05K 3/10; H05K 2201/0145; H05K 2201/0154; H05K 2201/0137

(57) ABSTRACT

There are provided a printed circuit board and a manufacturing method thereof. The printed circuit board (PCB) includes an adhesive film disposed between an insulating layer and a circuit pattern, wherein the adhesive film includes poly(glycidyl methacrylate). The printed circuit board may include the adhesive film between the circuit pattern and the insulating layer, and thus, adhesive strength may be increased, while having a low roughness value, a fine circuit pattern may be formed, and reliability thereof may be enhanced.

### CROSS-REFERENCE TO RELATED APPLICATION

This application claims the benefit of Korean Patent Application No. 10-2014-0017989 filed on Feb. 17, 2014, with the Korean Intellectual Property Office, the disclosure of which is incorporated herein by reference.

### BACKGROUND

The present disclosure relates to a printed circuit board and a manufacturing method thereof.

In general, a printed circuit board (PCB) is formed by forming wiring patterns with copper foil on one or both surfaces of a board formed of various thermosetting synthetic resins, fixedly disposing integrated circuits (ICs) or electronic components on the board, implementing electrical connections therebetween, and coating the board with an insulator.

The recent development of the electronics industry has triggered growing demand for multifunctional, lighter, thinner, shorter, and smaller electronic components, and in line therewith, printed circuit boards (PCBs) on which electronic components are mounted have also come to be required to have high density wiring patterns and to be thinned.

In particular, in manufacturing a PCB, in an additive method or a semi-additive process (SAP) method, an insulating layer formed of a resin is desmeared to have increased roughness and is subsequently plated, or a copper circuit is subjected to a roughening treatment and coated with a resin to secure adhesive strength between the resin and the plated layer.

However, a PCB manufactured in such a manner has too high a degree of roughness to form a fine circuit and involves a great deal of loss in signal transmissions.

In order to overcome the shortcomings, the manufacturing of boards having a low degree of roughness has been attempted, but such boards may have a low degree of adhesive strength between a resin and a circuit due to low degree of roughness, degrading reliability.

To resolve the drawbacks, Patent Document 1 proposes methods for securing a high degree of adhesive strength with a low degree of roughness using an adhesive or a tin plating solution.

However, these methods employ a wet process with an adhesive, a tin plating solution, or the like, increasing process costs and causing the need for periodical solution management.

### RELATED ART DOCUMENT

### (Patent Document 1) Korean Patent Laid-Open Publication No. 2010-0050422

### SUMMARY

An exemplary embodiment in the present disclosure may provide a printed circuit board (PCB) in which an adhesive film is provided to increase adhesive strength between an insulator and a circuit pattern, thus obtaining high interlayer adhesive strength with a low degree of roughness, and a manufacturing method thereof.

According to an exemplary embodiment in the present disclosure, a printed circuit board (PCB) may include: an adhesive film formed between an insulating layer and a circuit pattern, wherein the adhesive film includes poly(glycidyl methacrylate).

The adhesive film may include one or more of an amine-based polymer, an imidazole-based polymer, and a pyridine-based polymer.

The adhesive film may further include an aromatic compound.

The aromatic compound may be one or more selected from the group consisting of divinyl benzene, styrene, and ethyl benzene.

The adhesive film may be formed by bonding poly (glycidyl methacrylate) to the insulating layer.

The adhesive film may be formed by bonding one or more of an amine-based polymer, an imidazole-based polymer, and a pyridine-based polymer to the circuit pattern.

According to an exemplary embodiment in the present disclosure, a printed circuit board (PCB) may include: an adhesive film formed between an insulating layer and a circuit pattern, wherein the adhesive film includes a plurality of layers, and at least one of the plurality of layers forming the adhesive film includes poly(glycidyl methacrylate).

The adhesive film may include a first adhesive layer and a second adhesive layer, and the first adhesive layer may include poly(glycidyl methacrylate) while the second adhesive layer may include one or more of an amine-based polymer, an imidazole-based polymer, and a pyridine-based polymer.

The first adhesive layer may be adhesively formed on the insulating layer.

The second adhesive layer may be adhesively formed on the circuit pattern.

The first adhesive layer may further include an aromatic compound.

The aromatic compound may be one or more selected from the group consisting of divinyl benzene, styrene, and ethyl benzene.

According to an exemplary embodiment in the present disclosure, a method of manufacturing a printed circuit board (PCB) may include: forming an adhesive film between an insulating layer and a circuit pattern, wherein the adhesive film includes poly(glycidyl methacrylate).

The forming of an adhesive film may include: forming a circuit pattern on the insulating layer; forming the adhesive film on the insulating layer with the circuit pattern formed thereon; and forming an upper insulating layer on the adhesive film.

The upper insulating layer may include a solder resist (SR) layer.

The forming of an adhesive film may include: forming the adhesive film on the insulating layer; forming a copper plating layer on the adhesive film; and performing a patterning process on the copper plating layer to form a circuit pattern.

The adhesive film may be formed by performing one or more processes selected from the group consisting of chemical vapor deposition (CVD), initiated chemical vapor deposition (iCVD), and spin coating.

The adhesive film may include a first adhesive layer and a second adhesive layer, and the first adhesive layer may include poly(glycidyl methacrylate) while the second adhesive layer may include one or more of an amine-based polymer, an imidazole-based polymer, and a pyridine-based polymer.

The first adhesive layer may be adhesively formed on the insulating layer, while the second adhesive layer may be adhesively formed on the circuit pattern.

The first adhesive layer may further include an aromatic compound.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a cross-sectional view illustrating a printed circuit board (PCB) according to an exemplary embodiment of the present disclosure;

FIG. 2 is a cross-sectional view illustrating a PCB according to an exemplary embodiment of the present disclosure;

FIG. 3 is a cross-sectional view illustrating a PCB according to another exemplary embodiment of the present disclosure;

FIG. 4 is a cross-sectional view illustrating a PCB according to another exemplary embodiment of the present disclosure;

FIG. 5 is a cross-sectional view illustrating sequential processes in a method of manufacturing a PCB according to the exemplary embodiment of FIGS. 1 and 2;

FIGS. 6A through 6H are cross-sectional views illustrating sequential processes in a method of manufacturing a PCB according to the exemplary embodiment of FIGS. 3 and 4; and

FIG. 7 is a view illustrating a process of forming an adhesive film according to an exemplary embodiment of the present disclosure.

### DETAILED DESCRIPTION

Hereinafter, embodiments in the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

Printed Circuit Board

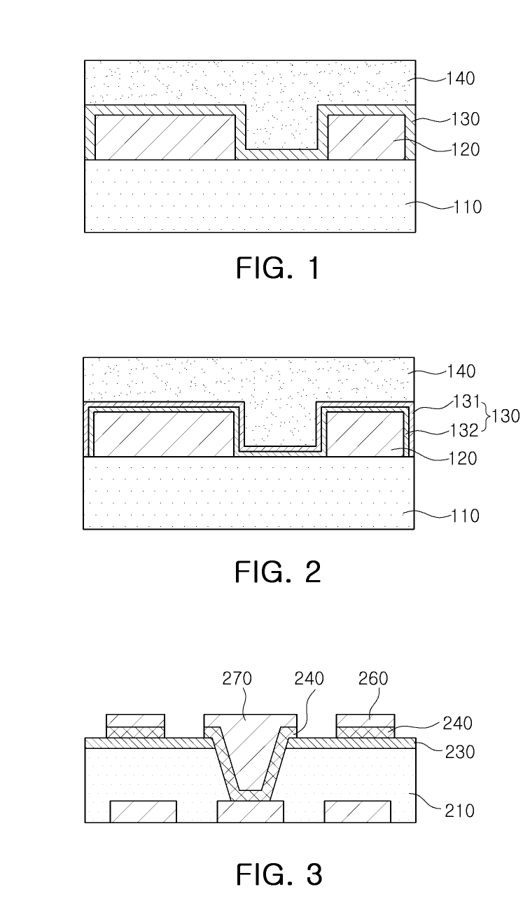

FIGS. 1 and 2 are cross-sectional views illustrating a printed circuit board (PCB) according to an exemplary embodiment of the present disclosure.

Referring to FIG. 1, a PCB according to an exemplary embodiment of the present disclosure includes an adhesive film 130 formed between an insulating layer 140 and a circuit pattern 120. The adhesive film 130 includes poly (glycidyl methacrylate).

With this structure, adhesive strength with respect to the circuit pattern 120 and the insulating layer 140 may be increased without a roughening process such as in the related art.

The adhesive film 130 may further include one or more of an amine-based polymer, an imidazole-based polymer, and a pyridine-based polymer.

The adhesive film 130 may further include an aromatic compound, and the aromatic compound may be one or more selected from the group consisting of divinyl benzene, styrene, and ethyl benzene.

The poly(glycidyl methacrylate) of the adhesive film 130 may be adhesively formed on the insulating layer 140, and one or more of an amine-based polymer, an imidazole-based polymer, and an pyridine-based polymer of the adhesive film 130 may be adhesively formed on the circuit pattern 120, whereby adhesive strength of both sides between heterogeneous interfaces may be increased.

Referring to FIG. 2, the adhesive film 130 according to an exemplary embodiment of the present disclosure may include a plurality of layers. For example, the adhesive film 130 may include a first adhesive layer 131 and a second adhesive layer 132.

At least one layer forming the adhesive film 130 may include poly(glycidyl methacrylate).

For example, the first adhesive layer 131 may include poly(glycidyl methacrylate), while the second adhesive layer 132 may include one or more of an amine-based polymer, an imidazole-based polymer, and a pyridine-based polymer.

The first adhesive layer 131 may further include an aromatic compound, and the aromatic compound may be one or more selected from the group consisting of divinyl benzene, styrene, and ethyl benzene.

The first adhesive layer 131 may be adhesively formed on the insulating layer 140 while the second adhesive layer 132 may be adhesively formed on the circuit pattern 120, and thus, adhesive strength of both sides between heterogeneous interfaces may be increased.

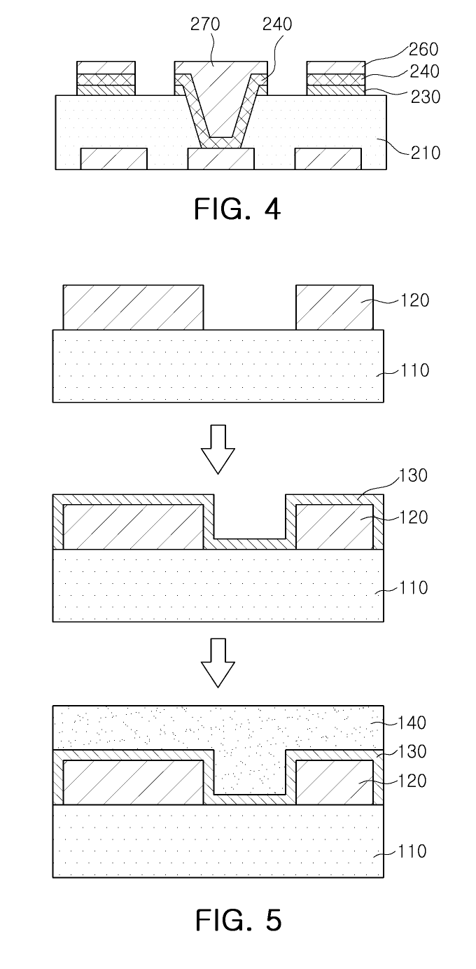

FIGS. 3 and 4 are cross-sectional views illustrating a PCB according to another exemplary embodiment of the present disclosure.

As in the exemplary embodiments of FIGS. 1 and 2, in the exemplary embodiments of FIGS. 3 and 4, an adhesive film is formed between an insulating layer and a circuit pattern. However, the exemplary embodiments of FIGS. 1 and 2 have a structure in which the insulating layer is stacked on the circuit pattern, while the exemplary embodiments of FIGS. 3 and 4 have a structure in which a circuit pattern is formed on an insulating layer.

Referring to FIG. 3, an adhesive film 230 is formed on an insulating layer 210, and circuit patterns 240 and 260 are formed on the adhesive film 230. The circuit patterns 240 and 260 may be formed by sequentially stacking an electroless copper plating layer 240 and an electro-copper plating layer 260. Vias 240 and 270 electrically connecting the upper and lower circuit patterns 240 and 260 may also be formed of an electroless copper plating layer 240 and an electro-copper plating layer 270.

Thus, since the insulating layer 210 and the circuit patterns 240 and 260 are bonded by the adhesive film 230, although surface roughness of the insulating layer 210 is low, sufficient adhesion may be secured.

As in the exemplary embodiments of FIGS. 1 and 2, the adhesive film 230 may include a first adhesive layer adhered to the insulating layer 210 and a second adhesive layer adhered to the circuit patterns 240 and 260. The first adhesive layer may include poly(glycidyl methacrylate), while the second adhesive layer may include one or more of an amine-based polymer, an imidazole-based polymer, and a pyridine-based polymer.

The exemplary embodiment of FIG. 4 is identical to the exemplary embodiment of FIG. 3, except that the adhesive film 230 is formed only on the portions of the circuit patterns 240 and 260, and thus, a detailed description thereof will be omitted.

Method of Manufacturing PCB

FIG. 5 is a cross-sectional view illustrating sequential processes in a method of manufacturing a PCB according to the exemplary embodiment of FIGS. 1 and 2.

Referring to FIG. 5, after a circuit pattern 120 is formed on an insulating layer 110, an adhesive film 130 may be formed on the insulating layer 110 with the circuit pattern 120 formed thereon. The adhesive film 130 may have a thickness ranging from 0.01 μm to 1 μm.

The adhesive film 130 may include poly(glycidyl methacrylate) and may further include one or more of an amine-based polymer, an imidazole-based polymer, and a pyridine-based polymer. The adhesive film 130 may further include an aromatic compound, and the aromatic compound may be one or more selected from the group consisting of divinyl benzene, styrene, and ethyl benzene.

Here, the adhesive film 130 may be formed by bonding a film containing one or more of an amine-based polymer, an imidazole-based polymer, and a pyridine-based polymer bonded so as to be adjacent to the circuit pattern 120 and forming a film containing poly(glycidyl methacrylate) thereon.

An upper insulating layer 140 may be formed on an upper surface of the adhesive film 130. The upper insulating layer 140 may be, for example, a solder resist (SR) layer.

The adhesive film 130 may increase adhesive strength with respect to the circuit pattern 120 using one of more of an amine-based polymer, an imidazole-based polymer, and a pyridine-based polymer and adhesive strength with respect to the upper insulating layer 140 using poly(glycidyl methacrylate).

Thus, since the PCB having the adhesive film 130 according to an exemplary embodiment of the present disclosure has increased adhesive strength with respect to the circuit pattern 120 and the upper insulating layer 140, reliability thereof may be enhanced.

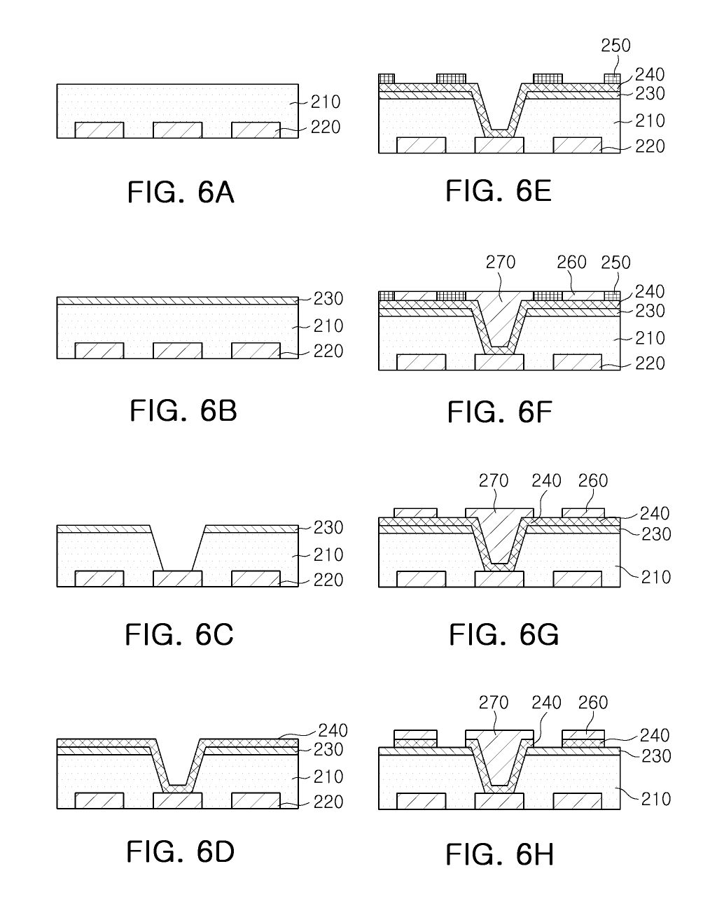

FIGS. 6A through 6H are cross-sectional views illustrating sequential processes in a method of manufacturing a PCB according to the exemplary embodiment of FIGS. 3 and 4.

Referring to FIG. 6, after an insulating layer 210 is provided (process 6A), an adhesive film 230 may be formed on the insulating layer 210 (process 6B). The adhesive film 230 may have a thickness ranging from 0.01 μm to 1 μm.

The adhesive film 230 may include poly(glycidyl methacrylate) and may further include one or more of an amine-based polymer, an imidazole-based polymer, and a pyridine-based polymer. The adhesive film 230 may further include an aromatic compound, and the aromatic compound may be one or more selected from the group consisting of divinyl benzene, styrene, and ethyl benzene.

Here, the adhesive film 230 may be formed by first bonding a film containing poly(glycidyl methacrylate) to the insulating layer 210 and forming a film containing one or more of an amine-based polymer, an imidazole-based polymer, and a pyridine-based polymer thereon.

After forming the adhesive film 230, a via hole may be formed with a laser (process 6C). The via hole exposes a lower circuit pattern 220. Thereafter, electroless copper plating is performed to form an electroless copper plating layer 240 on the adhesive film 230 and within the via hole (process 6D).

The copper plating layer 240 may undergo a patterning process including lithography and etching process so as to be changed to a fine circuit pattern.

Namely, a patterned plated resist 250 is attached to the electroless copper plating layer 240 (process 6E), and electro-plating is performed thereon to form an electro-plated layer 260 (process 6F). Thereafter, the plated resist 250 is removed (process 6G) and the electroless copper plating layer 240 is etched to form a fine circuit pattern (process 6H). Thereafter, a process of removing the adhesive film 230 formed in a region other than the circuit pattern may be further performed (please refer to FIG. 4).

The adhesive film 230 may have low roughness (Ra) value of, for example, 0.1 μm or less, for example, while increasing adhesive strength with respect to the electroless copper plating layer 240, thus contributing to forming the electroless copper plating layer 240 as a fine circuit pattern.

Thus, the method of manufacturing a PCB according to an exemplary embodiment of the present disclosure may provide a PCB having a fine circuit pattern using the adhesive film 230 having enhanced adhesive strength with respect to the copper plating layer 250, while having a low roughness value.

The adhesive films 130 and 230 according to an exemplary embodiment of the present disclosure may be formed by performing one or more processes selected from the group consisting of chemical vapor deposition (CVD), initiated chemical vapor deposition (iCVD), and spin coating.

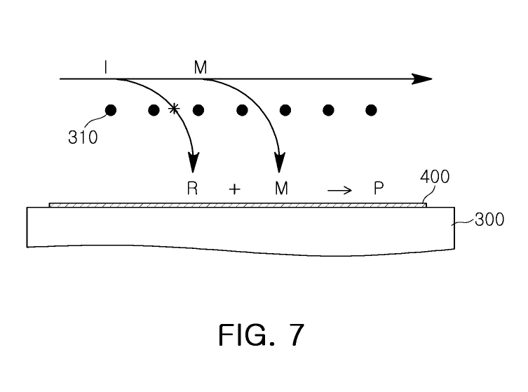

FIG. 7 is a view illustrating a process of forming an adhesive film according to an exemplary embodiment of the present disclosure.

Referring to FIG. 7, according to the iCVD method, a polymer thin film P may be formed through vapor polymerization in which polymerization and film forming process are simultaneously performed by vaporizing a monomer M of polymer constituting the adhesive film within a chamber. Through the iCVD, the initiator I and the monomer M may be vaporized and chain-polymerized in a vapor phase using a free radical R, whereby the polymer thin film P may be deposited on a surface of a board 300 including a circuit pattern or an insulating layer.

When the initiator I and the monomer M are simply mixed, polymerization does not occur, but when the initiator I is decomposed by a filament 310 having a high temperature positioned within the iCVD chamber to generate the radical R, the monomer M is activated to cause chain-polymerization.

As the initiator I, peroxide such as tert-butylperoxide (TBPO), tert-amyl peroxide (TAPO), or the like, is largely used. The initiator I, a volatile material having a boiling point of about 110° C., may be thermally decomposed at about 150° C.

Thus, when the high temperature filament 310 used in the iCVD chamber is maintained at about 200° C. to 250° C., chain polymerization may be easily induced. Here, the temperature of the filament 310 is sufficiently high to thermally decompose the initiator I of the peroxide, but most organic substances including the monomer M used in the iCVD are not thermally decomposed at such a temperature.

The free radical R formed by decomposing the initiator I may be delivered to the monomer M to cause chain polymerization to form the polymer P. The polymer P formed thusly may be deposited on the board 300 maintained at a low temperature to form an adhesive film 400.

In a spin coating method, an adhesive film solution for forming an adhesive film may be applied dropwise to a surface of a board installed in a spin coater.

Thereafter, through rotary force of the spin coater in which the board is installed, the adhesive film solution may be applied to the entirety of the board including the circuit pattern or the insulating layer formed thereon.

Subsequently, the applied adhesive film solution is cured so a volatile organic solvent is volatized to be removed, an adhesive film may be formed on the board including a circuit pattern and an insulating layer.

The adhesive film 130 according to an exemplary embodiment of the present disclosure may include a plurality of layers. For example, the adhesive film 130 may include a first adhesive layer 131 and a second adhesive layer 132.

At least one of the plurality of layers forming the adhesive film 130 may include poly(glycidyl methacrylate).

For example, the first adhesive layer 131 may include poly(glycidyl methacrylate) while the second adhesive layer 132 may include one or more of an amine-based polymer, an imidazole-based polymer, and a pyridine-based polymer.

The first adhesive layer 131 may further include an aromatic compound, and the aromatic compound may be one or more selected from the group consisting of divinyl benzene, styrene, and ethyl benzene.

Here, the first adhesive layer 131 may be adhesively formed on the insulating layer 140, while the second adhesive layer 132 may be adhesively formed on the circuit pattern 120. Thus, adhesive strength of both sides between heterogeneous interfaces may be increased.

As set forth above, the PCB according to exemplary embodiments of the present disclosure includes an adhesive film between a circuit pattern and an insulating layer, and thus, adhesive strength may be increased, while having a low roughness value, a fine circuit pattern may be formed, and reliability thereof may be enhanced.

While exemplary embodiments have been shown and described above, it will be apparent to those skilled in the art that modifications and variations could be made without departing from the spirit and scope of the present disclosure as defined by the appended claims.

What is claimed is:

1. A printed circuit board (PCB) comprising an adhesive film disposed between an insulating layer and a circuit pattern,
wherein the adhesive film includes poly(glycidyl methacrylate).

2. The printed circuit board of claim 1, wherein the adhesive film includes one or more of an amine-based polymer, an imidazole-based polymer, and a pyridine-based polymer.

3. The printed circuit board of claim 1, wherein the adhesive film further includes an aromatic compound.

4. The printed circuit board of claim 3, wherein the aromatic compound is one or more selected from the group consisting of divinyl benzene, styrene, and ethyl benzene.

5. The printed circuit board of claim 1, wherein the adhesive film is formed by bonding poly(glycidyl methacrylate) to the insulating layer.

6. The printed circuit board of claim 2, wherein the adhesive film is formed by bonding one or more of an amine-based polymer, an imidazole-based polymer, and a pyridine-based polymer to the circuit pattern.

7. A printed circuit board (PCB) comprising an adhesive film formed between an insulating layer and a circuit pattern,
wherein the adhesive film includes a plurality of layers, and at least one of the plurality of layers forming the adhesive film includes poly(glycidyl methacrylate).

8. The printed circuit board of claim 7, wherein the adhesive film includes a first adhesive layer and a second adhesive layer, and the first adhesive layer includes poly(glycidyl methacrylate) while the second adhesive layer includes one or more of an amine-based polymer, an imidazole-based polymer, and a pyridine-based polymer.

9. The printed circuit board of claim 8, wherein the first adhesive layer is adhesively formed on the insulating layer.

10. The printed circuit board of claim 8, wherein the second adhesive layer is adhesively formed on the circuit pattern.

11. The printed circuit board of claim 8, wherein the first adhesive layer further includes an aromatic compound.

12. The printed circuit board of claim 11, wherein the aromatic compound is one or more selected from the group consisting of divinyl benzene, styrene, and ethyl benzene.

13. A method of manufacturing a printed circuit board (PCB), the method comprising forming an adhesive film between an insulating layer and a circuit pattern,
wherein the adhesive film includes poly(glycidyl methacrylate).

14. The method of claim 13, wherein the forming of an adhesive film includes:
forming a circuit pattern on the insulating film;
forming the adhesive film on the insulating layer with the circuit pattern formed thereon; and
forming an upper insulating layer on the adhesive film.

15. The method of claim 14, wherein the upper insulating layer includes a solder resist (SR) layer.

16. The method of claim 13, wherein the forming of an adhesive film includes:
forming the adhesive film on the insulating layer;
forming a copper plating layer on the adhesive film; and
performing a patterning process on the copper plating layer to form a circuit pattern.

17. The method of claim 13, wherein the adhesive film is formed by performing one or more processes selected from the group consisting of chemical vapor deposition (CVD), initiated chemical vapor deposition (iCVD), and spin coating.

18. The method of claim 13, wherein the adhesive film includes a first adhesive layer and a second adhesive layer, and the first adhesive layer includes poly(glycidyl methacrylate) while the second adhesive layer includes one or more of an amine-based polymer, an imidazole-based polymer, and a pyridine-based polymer.

19. The method of claim 18, wherein the first adhesive layer is adhesively formed on the insulating layer, while the second adhesive layer is adhesively formed on the circuit pattern.

20. The method of claim 18, wherein the first adhesive layer further includes an aromatic compound.
